(19) United States
(12) Patent Application Publication
(10) Pub. No.: US 2021/0150086 A1
(43) Pub. Date: May 20, 2021

(54) METHODS, SYSTEMS, AND MEDIA FOR GENERATIVE URBAN DESIGN WHERE MAPS ARE GENERATED USING FRACTALS

(71) Applicant: Sidewalk Labs LLC, New York, NY (US)

(72) Inventors: Douwe Osinga, New York, NY (US); Difei Chen, New York, NY (US); Violet Whitney, Long Island City, NY (US); Kabir Soorya, Long Island City, NY (US); Jack Amadeo, Brooklyn, NY (US); Brian Ho, New York, NY (US); Okalo Ikhena, New York, NY (US); Amanda Meurer, Brooklyn, NY (US); Samara Trilling, New York, NY (US); Dan Vanderkam, Brooklyn, NY (US)

(21) Appl. No.: 16/951,627

(22) Filed: Nov. 18, 2020

Related U.S. Application Data
(60) Provisional application No. 62/936,834, filed on Nov. 18, 2019.

(51) Int. Cl. G06F 30/13; G06F 30/23; G06T 17/05; G06T 17/20

(52) U.S. Cl. CPC G06F 30/13; G06T 17/20; G06T 17/05; G06F 30/23

(57) ABSTRACT

Methods, systems, and media for generative urban design where maps are generated using fractals are provided. In some embodiments, the method comprises: identifying, using a hardware processor, area information for a particular geographic location; identifying, using the hardware processor, fractal generation parameters; generating, using the hardware processor, a fractal using the fractal generation parameters; generating, using the hardware processor, an array that represents the particular geographic location based on the fractal and the area information; and generating, using the hardware processor, one or more maps of the particular geographic location using the array.

### CROSS-REFERENCE TO RELATED APPLICATIONS

This application claims the benefit of U.S. Provisional Patent Application No. 62/936,834, filed Nov. 18, 2019, which is hereby incorporated by reference herein in its entirety.

### TECHNICAL FIELD

The disclosed subject matter relates to methods, systems, and media for generative urban design where maps are generated using fractals.

### BACKGROUND

When designing or modifying a city, town, or other geographic location, it may be useful to generate a map of the geographic location that includes a layout of the geographic location and allocates portions of the location to different spatial attributes (e.g., land uses). For example, an urban designer may want to allocate portions of a geographic location to green space, such as parks and playgrounds, and portions of the geographic location to residential areas. However, it can be difficult to generate a map of the geographic location that allocates regions of the geographic location to different areas and/or different usages. For example, there may be particular constraints, such as that ideally 10% of the geographic location should be allocated for green space, and it can be difficult to design a map subject to the constraints. Additionally, there may be many possible maps of a geographic location that satisfy particular constraints. For example, a map that is to be generated that allocates 10% of the area to green space could be generated with several small parks, with one large park, with several parks along an edge of the geographic location represented by the map, with one large park at an edge of the geographic location represented by the map, etc. However, it can be difficult to generate maps that fully explore the many potential layouts or arrangements of a geographic location.

Accordingly, it is desirable to provide new methods, systems, and media for generative urban design where maps are generated using fractals.

### SUMMARY

Methods, systems, and media for generative urban design where maps are generated using fractals are provided.

In accordance with some embodiments of the disclosed subject matter, a method for generative design is provided, the method comprising: identifying, using a hardware processor, area information for a particular geographic location; identifying, using the hardware processor, fractal generation parameters; generating, using the hardware processor, a fractal using the fractal generation parameters; generating, using the hardware processor, an array that represents the particular geographic location based on the fractal and the area information; and generating, using the hardware processor, one or more maps of the particular geographic location using the array.

In some embodiments, the method further comprises: receiving a distribution of different land use types for the particular geographic location; and assigning one or more regions of the particular geographic location to one of a plurality of areas based on the distribution of different land use types for the particular geographic location.

In some embodiments, the array that represents the particular geographic location divides the particular geographic location into a plurality of cells each having a cell value and each cell of the plurality of cells is assigned to a land use type from a plurality of land use types based on the cell value. In some embodiments, a first range of cell values is assigned to a residential area, a second range of cell values is assigned to a commercial area, and a third range of cell values is assigned to a green space area.

In some embodiments, the array is an N-dimensional array and wherein the fractal is generated using a fractal generation algorithm. In some embodiments, a cell of the N-dimensional array is associated with a vector having elements that correspond to each of a plurality of land use types, and the vector indicates that a portion of the particular geographic location is allocated to a first percentage of residential area, a second percentage of commercial area, and a third percentage of green space area.

In some embodiments, the fractal generation parameters include a roughness parameter that modifies a roughness of edges within the fractal, the fractal is generated using the roughness parameter, a high roughness parameter scatters a land use type across the array, and a low roughness parameter generates clusters of the land use area in the array.

In accordance with some embodiments of the disclosed subject matter, a system for generative design is provided, the system comprising a memory and a hardware processor that, when configured to execute computer executable instructions stored in the memory, is configured to: identify area information for a particular geographic location; identify fractal generation parameters; generate a fractal using the fractal generation parameters; generate an array that represents the particular geographic location based on the fractal and the area information; and generate one or more maps of the particular geographic location using the array.

In accordance with some embodiments of the disclosed subject matter, a non-transitory computer-readable medium containing computer executable instructions that, when executed by a processor, cause the processor to perform a method for generative design is provided, the method comprising: identifying, using a hardware processor, area information for a particular geographic location; identifying, using the hardware processor, fractal generation parameters; generating, using the hardware processor, a fractal using the fractal generation parameters; generating, using the hardware processor, an array that represents the particular geographic location based on the fractal and the area information; and generating, using the hardware processor, one or more maps of the particular geographic location using the array.

In accordance with some embodiments of the disclosed subject matter, a system for generative design is provided, the system comprising: means for identifying area information for a particular geographic location; means for identifying fractal generation parameters; means for generating a fractal using the fractal generation parameters; means for generating an array that represents the particular geographic location based on the fractal and the area information; and means for generating one or more maps of the particular geographic location using the array.

### BRIEF DESCRIPTION OF THE DRAWINGS

Various objects, features, and advantages of the disclosed subject matter can be more fully appreciated with reference to the following detailed description of the disclosed subject matter when considered in connection with the following drawings, in which like reference numerals identify like elements.

FIG. 1 shows an example of a process for generating maps using fractals in accordance with some embodiments of the disclosed subject matter.

FIG. 2A shows an example of a fractal generated based on one or more fractal parameters in accordance with some embodiments of the disclosed subject matter.

FIG. 2B shows an example of a map generated based on a fractal in accordance with some embodiments of the disclosed subject matter.

FIG. 3 shows a schematic diagram of an illustrative system suitable for implementation of mechanisms described herein for generating maps using fractals in accordance with some embodiments of the disclosed subject matter.

FIG. 4 shows a detailed example of hardware that can be used in a server and/or a user device of FIG. 3 in accordance with some embodiments of the disclosed subject matter.

### DETAILED DESCRIPTION

In accordance with various embodiments, mechanisms (which can include methods, systems, and media) for generative urban design where maps are generated using fractals are provided.

It should be noted that these maps can be used in any suitable generative design process. For example, a map that conveys a spatial attribute (e.g., land use) and density can be used as an input to the generative design process. In a more particular example, a map can represent a grid applied to an urban site in which each point stores spatial attributes for use (e.g., residential, commercial, etc.) and density (e.g., floor area ratio). The map can be used by the generative design process to generate various urban plans each having a particular combination of use and density for evaluation.

In some embodiments, the mechanisms described herein can generate a data structure representing an N-dimensional array that represents a geographic location using a fractal that is subject to any suitable constraints relating to portions of the N-dimensional array. For example, in some embodiments, the mechanisms can generate an N-dimensional array that represents a particular geographic location (e.g., a particular portion of land, and/or any other suitable geographic location) that assigns regions of the particular geographic location to particular types of areas and/or usage scenarios (e.g., based on a relative distribution of different use-types). As a more particular example, in some embodiments, the mechanisms can assign regions of a geographic location to types of areas and/or usage scenarios such as green space (e.g., where parks and/or playgrounds are to be constructed), residential areas (e.g., where houses, apartment buildings, etc. are to be constructed), commercial and/or retail areas (e.g., where shops, businesses, factories, etc. are to be constructed), and/or any other suitable types of areas.

In some embodiments, the mechanisms can generate an N-dimensional array based on a fractal using any suitable technique or combination of techniques. For example, in some embodiments, the mechanisms can generate a fractal using any suitable fractal generation algorithm (e.g., a midpoint algorithm, a diamond/square algorithm, and/or any other suitable algorithm). In some such embodiments, a generated fractal can have cells, each with a value. In some embodiments, the mechanisms can then generate an N-dimensional array by assigning each cell of the fractal to a type of area or a land use (e.g., green space, residential, commercial, retail, etc.) based on a value of the fractal for the cell. For example, in some embodiments, cells with values within a first range can be allocated as green space, and cells with values within a second range can be allocated as residential area. In some such embodiments, each element in an N-dimensional array can correspond to a different type of land use, and each element of the N-dimensional array can be assigned based on corresponding values of cells of the fractal. For example, in some embodiments, a first cell of an N-dimensional array can correspond to a particular portion of a geographic location, and the first cell can be associated with a first vector that has elements corresponding to land uses, such as green space, office space, residential space, etc. Continuing with this example, in some embodiments, the elements of the first vector of the first cell of the N-dimensional array of vectors can be: [0.5, 0.3, 0.2], indicating that the portion of the geographic location corresponding to the first cell of the N-dimensional array is to be 50% green space, 30% office space, and 20% residential space.

In some embodiments, the mechanisms can then generate a map of a geographic location using an N-dimensional array generated based on a fractal. For example, in some embodiments, the mechanisms can place parks, office buildings, residential buildings, etc. at particular locations within a map of a geographic location based on an allocation of land use indicated in an N-dimensional array. As a more particular example, in an instance where an N-dimensional array representing a geographic location indicates that a particular portion of the geographic location is to be 50% green space, 30% office space, and 20% residential space, the mechanisms can generate a map that includes a park, one or more office buildings, and/or one or more residential buildings subject to the allocation indicated in a corresponding cell of the N-dimensional array. Note that, although land use is generally used herein to refer to allocation of regions within a geographic location for different purposes (e.g., green space, office space, commercial space, residential space, etc.), in some embodiments, land use can refer to any suitable type of spatial attribute for a region. For example, in some embodiments, land use can refer to a designation of a region as approved for particular types of construction, designation of a region as not approved for any types of construction, designation of a particular road or portion of a road as closed to vehicular traffic, and/or any other suitable type of spatial attribute(s) for regions.

In some embodiments, one or more fractal parameters can be used to generate fractals with different characteristics, which can then be reflected in N-dimensional arrays generated using the fractals. For example, in some embodiments, the mechanisms can generate a fractal using a roughness parameter, which can change a roughness of edges within a fractal. In some such embodiments, generating an N-dimensional array based on a fractal generated with a high roughness parameter can cause a particular type of area to be scattered across the N-dimensional array (e.g., multiple smaller parks rather than a single large park, etc.). Conversely, generating an N-dimensional array based on a fractal generated with a low roughness parameter can cause the N-dimensional array to include larger clusters of a particular type of area (e.g., a single large park rather than many smaller parks, etc.). As another example, in some embodiments, the mechanisms can generate a fractal using a density parameter, which can change whether particular types of areas are clustered in particular portions of the N-dimensional array (e.g., whether a green space is allocated at the edges of a N-dimensional array or in the center of a N-dimensional array, and/or within any other suitable portions of the N-dimensional array).

In some embodiments, the mechanisms described herein can generate multiple N-dimensional arrays corresponding to a particular geographic location, thereby allowing multiple potential maps of a particular geographic location to be generated based on the multiple N-dimensional arrays. For example, in some embodiments, the mechanisms can be used to generate multiple potential N-dimensional arrays, each using different fractals generated using a different combination of fractal parameters. As a more particular example, in some embodiments, a first N-dimensional array can be generated using a low roughness parameter for the underlying fractal, and a second N-dimensional array can be generated using a high roughness parameter for the underlying fractal. Continuing with this example, in some embodiments, a first potential map and a second potential map can be generated of the geographic location based on the first N-dimensional array and the second N-dimensional array, respectively. By generating multiple potential maps of a single geographic location, the mechanisms described herein can allow users to explore different allocations of a geographic location, such as a map with many parks rather than a single large park. In addition, by generating multiple potential maps of a single geographic location, the mechanisms described herein can transmit or otherwise pass these multiple maps to an automated system for further processing.

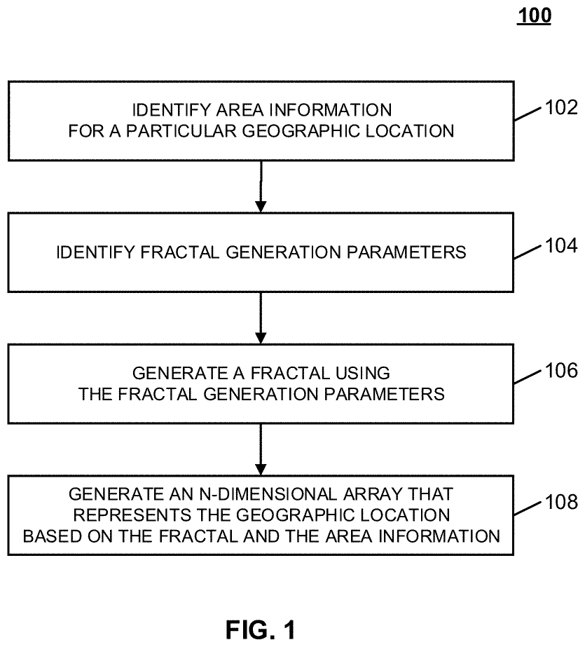

Turning to FIG. 1, an example 100 of a process for generating maps using fractals that can be used in accordance with some embodiments of the disclosed subject matter is shown. In some embodiments, blocks of process 100 can be executed by any suitable device, such as a server executing a program to simulate or generate a layout of a geographic location, a user device executing a program to simulate or generate a layout of a geographic location, and/or any other suitable device.

Process 100 can begin at 102 by identifying area information for a particular geographic location. In some embodiments, the geographic location can be any suitable geographic location of any suitable size, such as a city, a town, an unincorporated region, and/or any other suitable location. In some embodiments, the area information can include any suitable information related to any suitable portions of the geographic location. For example, in some embodiments, the area information can indicate natural boundaries within the geographic location, such as borders of rivers, lakes, streams, mountains, etc. As another example, in some embodiments, the area information can indicate percentages of a generated map of the geographic location that are to be allocated to particular types of areas. As a more particular example, in some embodiments, the area information can indicate percentages of a generated map of the geographic location that are to be allocated to particular areas, such as green spaces, residential areas, commercial areas, retail areas, and/or any other suitable types of areas. As a specific example, in some embodiments, the area information can indicate that 20% of a generated map is to be allocated to green space, 50% is to be allocated to residential areas, 10% is to be allocated to commercial areas, and 20% is to be allocated to retail areas. Note that, although area allocations are indicated using percentages in the example given above, in some embodiments, areas of the geographic location can be allocated using any other suitable metric, such as Gross Floor Area (GFA), square footage, acres, and/or any other suitable metric.

In some embodiments, process 100 can identify the area information for the geographic location in any suitable manner. For example, in some embodiments, the area information can be specified within an N-dimensional array representing the geographic location. As a more particular example, in some embodiments, an N-dimensional array representing the geographic location can divide the geographic location into blocks or cells of any suitable size, and each block or cell can indicate area information of the portion of the geographic location corresponding to the block or cell. Note that, in some such embodiments, an N-dimensional array representing the geographic location can divide the geographic location into any suitable number of blocks or cells (e.g., a 10×10 N-dimensional array that divides the geographic location into 100 blocks or cells, a 100×100 N-dimensional array that divides the geographic location into 10,000 blocks or cells, and/or any other suitable number). As another example, in some embodiments, the area information can be specified for the geographic location as a whole, rather than for particular blocks or cells of the geographic location. Note that, in some embodiments, process 100 can retrieve and/or access an N-dimensional array representing the geographic location in any suitable manner and from any suitable source.

At 104, process 100 can identify fractal generation parameters. Note that, in some embodiments, the fractal generation parameters can be related to any suitable fractal generation algorithm, such as a midpoint algorithm, a diamond/square algorithm, and/or any other suitable algorithm. In some embodiments, the fractal generation algorithm can use the fractal generation parameters to generate a fractal with any suitable output values, such as elevations or intensity values for each cell of the fractal, as described below in connection with block 106. In some embodiments, the generated fractal can be used to generate an N-dimensional array that represents the geographic location. For example, in some embodiments, process 100 can generate an N-dimensional array that represents the geographic location by assigning a type of area (e.g., green space, residential, commercial, retail, etc.) to each cell of the fractal based on the output value, as described below in connection with block 108. In some such embodiments, the N-dimensional array can then be used to generate a map of the geographic location, as described below in more detail in connection with block 108.

In some embodiments, the fractal generation parameters can include any suitable parameters to be used by a fractal generation algorithm to generate a fractal. For example, in some embodiments, the parameters can include a roughness parameter, R, that can indicate an amount of perturbation after each iteration of the fractal generation algorithm. As a more particular example, in some embodiments, a larger value of R can correspond to more scattered areas within a fractal, which can in turn generate a map with a larger number of parks each of a relatively smaller area. As another more particular example, in some embodiments, a smaller value of R can correspond to larger clusters of areas within a fractal, which can in turn generate a map with fewer parks each of a relatively larger area.

As another example, in some embodiments, the fractal generation parameters can include a density parameter that indicates a manner in which particular output values of the fractal are to be clustered. As a more particular example, in some embodiments, the density parameter can indicate that output values of the fractal that are to correspond to green space are to be clustered at a center region of the generated fractal. As another more particular example, in some embodiments, the density parameter can indicate that output values of the fractal that are to correspond to green space are to be clustered at an outer region of the generated fractal. As yet another more particular example, in some embodiments, the density parameter can indicate that output values of the fractal that are to correspond to residential areas are to be clustered near output values that correspond to green space.

In some embodiments, process 100 can identify the fractal generation parameters in any suitable manner. For example, in some embodiments, process 100 can receive the fractal generation parameters as input arguments of a fractal generation algorithm that is being executed. In some such embodiments, the algorithm can be executed on any suitable device, such as a user device, a server, and/or any other suitable type of device. In some embodiments, the parameters can be received from a user of a user device via a user interface presented on the user device.

At 106, process 100 can generate a fractal using the fractal generation parameters. In some embodiments, as described above in connection with block 104, process 100 can use any suitable fractal generation algorithm, such as a midpoint algorithm, a diamond/square algorithm, and/or any other suitable fractal generation algorithm. In some embodiments, process 100 can use any suitable initial values for generating the fractal. In some embodiments, process 100 can perform any suitable number of iterations in generating the fractal. In some embodiments, output values of the fractal can be elevations or intensities for each cell of the fractal generated by the fractal generation algorithm. For example, in some embodiments, process 100 can use a diamond/square algorithm that generates an elevation or height for each cell as a result of a series of perturbations or iterations.

Note that, in some embodiments, rather than generating a heightmap or elevation map, process 100 can generate a vector at each iteration by, for example, taking an average of four neighboring cell values and applying a mutation (e.g., a randomly selected mutation, and/or any other suitable type of mutation) to generate the vector value(s). In some embodiments, the generated vector value(s) can be generated based on a roughness parameter associated with the fractal and/or based on any other suitable fractal parameters.

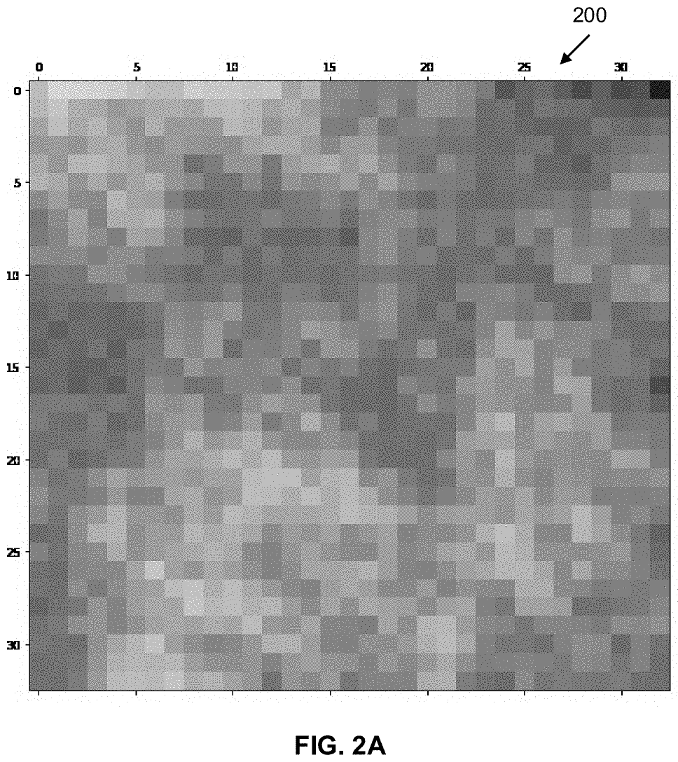

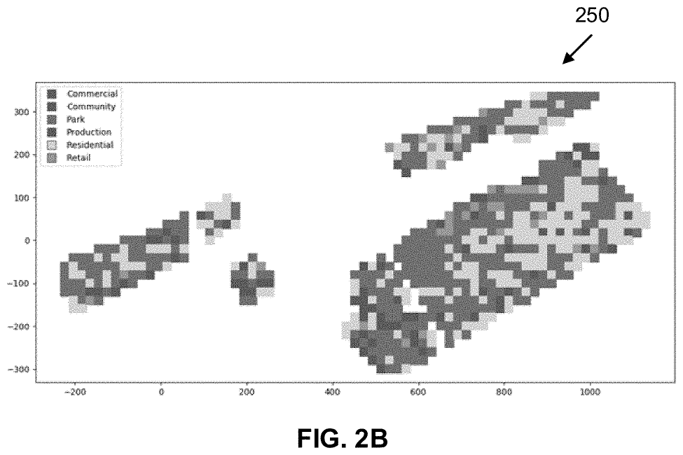

An example of a generated fractal 200 is shown in FIG. 2A. As illustrated, each cell of fractal 200 can have a different value (indicated by a color of the cell in FIG. 2A) that is determined by the fractal generation algorithm.

Referring back to FIG. 1, note that, in some embodiments, rather than generating a fractal, process 100 can generate an array using any suitable type of noise (e.g., Perlin noise, and/or any other suitable type of noise). In some embodiments, the array can have any suitable dimensions that can be determined, for example, based on a size of the geographic location for which a map is to be constructed, and/or based on any other suitable information. In some embodiments, process 100 can generate the array in any suitable manner. For example, in an instance in which process 100 generates the array using Perlin noise, process 100 can generate the array using any suitable parameters that specify a number of levels of detail to be included in the generated noise (e.g., a number of octaves, and/or any other suitable parameters), parameters that adjust frequencies included in the generated noise (e.g., a lacunarity, and/or any other suitable parameters), parameters that adjust an amplitude of each frequency included in the generated noise (e.g., a persistence, and/or any other suitable parameters), and/or any other suitable parameters. Note that, in some embodiments, a generated noise array can include values in any suitable range, such as between 0 and 1, between −1 and 1, and/or any other suitable range.

It should be noted that, in some embodiments, fractals can be replaced with one or more of: the output of any iterated process or function; the outputs of an I-system; the outputs of a cellular automation or similar system displaying emergent behavior caused by repeated application of one or more local rules to a group of individual, stateful units, where the rules may be conditional on the relationship of a given unit to other units and their state; outputs produced by any process or function, where the outputs display self similarity; outputs produced by any process or function, where the outputs display scale invariant phenomena; outputs produced by any process or function, where the outputs display self organized criticality; etc.

At 108, process 100 can generate a data structure representing an N-dimensional array that represents the geographic location based on the fractal generated at block 106 and the area information identified at block 102. In some embodiments, process 100 can generate the N-dimensional array that represents the geographic location based on the fractal and the area information using any suitable technique or combination of techniques. For example, in some embodiments, process 100 can assign cells of the fractal to a particular type of area (e.g., green space, residential, commercial, retail, and/or any other suitable type of area) based on values of the cells. As a more particular example, in some embodiments, cells with values (e.g., elevation values, heightmap values, intensity values, and/or any other suitable type of value) within a first range (e.g., between 0 and 10, between 0 and 100, and/or any other suitable range) can be assigned to a first type of area (e.g., green space, and/or any other suitable type of area), and cells with values within a second range (e.g., between 11 and 20, between 101 and 200, and/or any other suitable range) can be assigned to a second type of area (e.g., residential, and/or any other suitable type of area).

In some embodiments, the N-dimensional array that represents the geographic location can be an N-dimensional array where a particular cell is a vector, and where each element of each vector indicates a particular amount to be allocated to a particular type of land use for a corresponding portion of the geographic location. For example, in some embodiments, a first cell of the N-dimensional array can include a first vector that has elements corresponding to land uses such as green space, office space, and residential space. A more particular example of the first vector can be: [0.5, 0.3, 0.2], which can indicate that a portion of the geographic location corresponding to the first cell of the N-dimensional array is to have 50% green space, 30% office space, and 20% residential space. Similarly, a second cell of the N-dimensional array can include a second vector that is different (e.g., [0.3, 0.6, 0.1], indicating that a corresponding portion of the geographic location is to be 30% green space, 60% office space, and 10% residential space).

Note that, in some embodiments, process 100 can divide the range of cell values into any suitable number of ranges corresponding to any suitable number of types of areas to be allocated in the N-dimensional array that represents the geographic location. For example, in some embodiments, in an instance where there are four types of areas to be allocated, process 100 can determine four cell value ranges (e.g., 0 to 10, 11 to 20, 21-30, and 31-40, and/or any other suitable value ranges), each range corresponding to one of green space, residential, commercial, and retail. Note that, in some embodiments, each range of a group of ranges can be different, for example, a first range can be cell values from 0 to 10, and a second range can be cell values from 11 to 100. In some embodiments, process 100 can determine a group of ranges based on the area information. For example, in an instance where the area information indicates that 10% of a generated map is to correspond to green space, process 100 can determine a group of ranges such that a first range of the group of ranges encompasses 10% of the values of the fractal. Process 100 can then assign cells of the N-dimensional array with values that fall in the first range of the group of ranges to a green space area.

Additionally, note that, in instances in which process 100 generated a noise array at block 106 rather than generating a fractal, process 100 can generate the N-dimensional array at 108 based on the generated noise array. In some embodiments, process 100 can generate the N-dimensional array based on the noise array in any suitable manner and using any suitable technique(s). For example, in some embodiments, process 100 can generate the N-dimensional array based on values of elements in the noise array. As a more particular example, in some embodiments, process 100 can assign elements of the noise array to a particular type of area (e.g., green space, residential, commercial, retail, and/or any other suitable type of area) based on values of the elements. As a specific example, in some embodiments, elements of the noise array with values within a first range (e.g., between −1 and −0.8, between −1 and −0.5, and/or any other suitable range) can be assigned to a first type of area (e.g., green space, and/or any other suitable type of area), and elements of the noise array with values within a second range (e.g., between 0.4 and 0.8, between 0.9 and 1, and/or any other suitable range) can be assigned to a second type of area (e.g., residential, and/or any other suitable type of area). Note that, in some embodiments, each range can be different, for example, a first range that is assigned to a first type of area (e.g., green space) can be relatively small (e.g., values of the noise array between −1 and −0.8, and/or any other suitable relatively small range), and a second range that is assigned to a second type of area (e.g., residential) can be a relatively larger range (e.g., values of the noise array between −0.8 and 0.8, and/or any other suitable relatively larger range). Additionally, note that, similarly to as described above, in some embodiments, each range can be determined based on a number of areas to be allocated and/or based on the area information received at block 102. For example, in an instance in which two types of areas are to be allocated (e.g., residential and non-residential, and/or any other suitable two area types), and in which residential is to be allocated as 25% of a region and non-residential is to be allocated as 75% of the region (e.g., as indicated in area information received at block 102), and in which all elements of the noise array have values within a range between −1 and 1, process 100 can determine that elements of the noise array with values in a range between −1 and 0.5 are to be assigned as residential land use in the generated N-dimensional array, and elements of the noise array with values in a range between −0.49 and 1 are to be assigned as non-residential land use.

In some embodiments, the mechanisms can generate a map of the geographic location using the N-dimensional array using any suitable technique or combination of techniques. For example, in an instance where the N-dimensional array is a N-dimensional array where each cell of the array is associated with a vector, and where each vector indicates an allocation of land uses for a corresponding cell of the N-dimensional array, process 100 can generate a map subject to the allocation of land uses indicated by the vectors. As a more particular example, in an instance where a first cell of the N-dimensional array is associated with a first vector indicating that a first portion of the geographic location corresponding to the first cell is to be 50% green space, and where a second cell of the N-dimensional array is associated with a second vector indicating that a second portion of the geographic location corresponding to the second cell is to be 20% green space, process 100 can generate a map that includes one or more parks with a layout such that 50% of the first portion of the geographic location includes parks and 20% of the second portion of the geographic location includes parks. Note that, in some embodiments, process 100 can generate a map that allocates portions of the geographic location based on any suitable type of metric (e.g., percent of land use as described above, square feet, acres, and/or using any other suitable metric). Additionally, note that, in some embodiments, process 100 can use any suitable technique(s) to convert between different metrics. For example, in an instance in which cells of the N-dimensional array indicate land use allocation using percentage of land, and in an instance in which the map is to be generated based on square footage, process 100 can convert between percentage of land and square feet in any suitable manner.

An example of a map 250 generated using an N-dimensional array that was generated based on a fractal is shown in FIG. 2B in accordance with some embodiments of the disclosed subject matter. As illustrated, cells in map 250 can each be assigned to a different area of a group of areas, such as commercial, community, park, production, residential, and/or retail. Note that, in some embodiments, a group of areas can include any suitable number of areas (e.g., two, five, ten, and/or any other suitable number).

In some embodiments, a generated map can be presented in any suitable manner. For example, in some embodiments, a generated map can be presented in a user interface of a user device. As a more particular example, in some embodiments, in an instance where fractal generation parameters and/or area allocation values are received via a user interface, process 100 can cause the generated map to be presented in the user interface. In some embodiments, in instances where fractal generation parameters and/or area allocation values are received via a user interface, process 100 can update a generated map as parameters are changed, thereby allowing the user interface to update a map in near real-time as fractal generation parameters and/or area allocation values are changed.

Note that, in some embodiments, process 100 can be used to generate multiple potential maps of a particular geographic location. For example, in some embodiments, process 100 can be used to generate multiple potential maps, each subject to particular area allocation constraints (e.g., with 10% of space allocated for green space, with 30% of space allocated for residential buildings, and/or any other suitable constraints), but based on N-dimensional arrays generated using fractals associated with different fractal parameters (e.g., different roughness parameters, different density parameters, and/or different values or combinations of values of any suitable parameters). In some embodiments, process 100 can receive a series of fractal generation parameters (e.g., a group of roughness parameters, a group of density parameters, etc.), can generate a group of N-dimensional arrays corresponding to the different parameters, and can subsequently generate a corresponding group of maps each corresponding to a N-dimensional array of the group of N-dimensional arrays, thereby allowing a viewer of the maps to compare the different maps within one user interface.

Additionally, note that, in some embodiments, a generated map can be modified in any suitable manner. For example, in some embodiments, a generated map can be modified based on a user-supplied parameter. As a more particular example, a user-supplied parameter can include locations of one or more attractors corresponding to a type of land use (e.g., residential attractors, commercial attractors, and/or any other suitable type of attractors corresponding to a type of land use). As a specific example, in some embodiments, a user-supplied parameter can include a location of a residential attractor within a region represented by the generated map. Continuing with this example, in some embodiments, the mechanisms described herein can modify the generated map based on the location of the residential attractor. For example, in some embodiments, the mechanisms can modify the generated map such that areas within the map are re-allocated in any suitable manner based on the residential attractor. As a more particular example, in some embodiments, regions within the map that are relatively closer to the residential attractor relative to other regions can be re-allocated to residential land use, and regions that are relatively farther from the residential attractor can be re-allocated to other types of land use. Note that, in some embodiments, the mechanisms can cause the map to be modified based on the user-supplied parameters subject to any constraints used to generate the initial map, as described above. For example, in some embodiments, in an instance where a particular region is to include a particular percentage of area allocated to a particular land use (e.g., 30% residential buildings, 50% green space, 20% commercial buildings, and/or any other suitable allocation), the map can be modified such that the region maintains the percentage allocation, but that sub-regions within the larger region are re-allocated based on the user-supplied parameters.

In some embodiments, any suitable constraints that are used to generate a map can be treated as optional constraints or as soft constraints that can be satisfied with values within a predetermined range. For example, in some embodiments, a percentage allocation of area to different land uses can be treated as a constraint that can be satisfied if a percentage allocated to each area is within a predetermined range of a target allocation. As a more particular example, in an instance in which a map is to be generated which allocates 30% of a region to residential areas, a generated map can be deemed as satisfying the constraint a predetermined range (e.g., 25-35%, 28-32%, 30-35%, and/or any other suitable range) is allocated to residential areas. As another example, in some embodiments, a particular constraint can be indicated as an optional constraint that does not have to be satisfied by a generated map. In some embodiments, different constraints can be indicated as optional or as soft in any suitable manner, for example, via a user interface that allows a user of the user interface to mark particular constraints as optional, provide a range of values that are to acceptable values for a particular parameter, and/or to provide any other suitable user input.

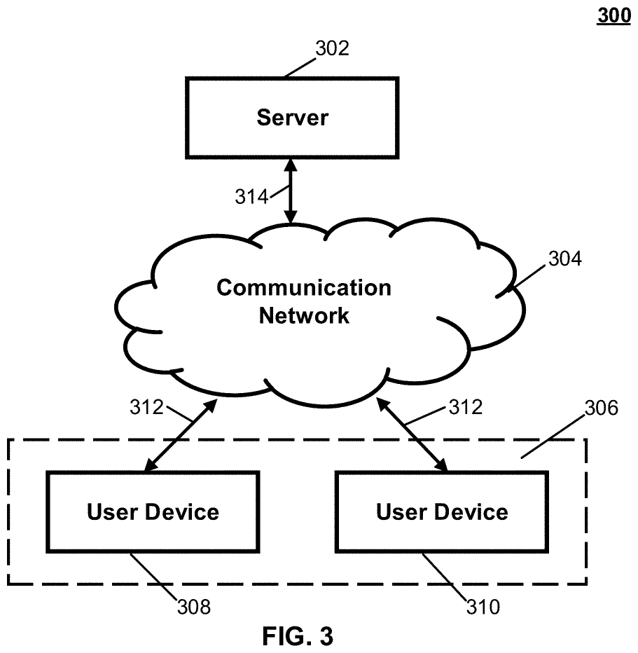

Turning to FIG. 3, an example 300 of hardware for generating maps using fractals that can be used in accordance with some embodiments of the disclosed subject matter is shown. As illustrated, hardware 300 can include a server 302, a communication network 304, and/or one or more user devices 306, such as user devices 308 and 310.

Server 302 can be any suitable server(s) for storing information, data, programs, and/or any other suitable content. For example, in some embodiments, server 302 can store any suitable map information, such as information indicating percentages or amounts of a particular parcel of a geographic location that is to be allocated to particular types of space (e.g., green space, residential space, commercial space, etc.). In some embodiments, server 302 can execute any suitable functions for generating an N-dimensional array that represents a geographic location using a fractal and subject to any suitable allocation constraints. For example, as described above in connection with FIG. 1, server 302 can use a fractal to allocate portions of an N-dimensional array representing a geographic location to green space (e.g., parks and/or playgrounds, etc.), residential areas, commercial areas, retail areas, and/or any other suitable areas.

Communication network 304 can be any suitable combination of one or more wired and/or wireless networks in some embodiments. For example, communication network 304 can include any one or more of the Internet, an intranet, a wide-area network (WAN), a local-area network (LAN), a wireless network, a digital subscriber line (DSL) network, a frame relay network, an asynchronous transfer mode (ATM) network, a virtual private network (VPN), and/or any other suitable communication network. User devices 306 can be connected by one or more communications links (e.g., communications links 312) to communication network 304 that can be linked via one or more communications links (e.g., communications links 314) to server 302. The communications links can be any communications links suitable for communicating data among user devices 306 and server 302 such as network links, dial-up links, wireless links, hard-wired links, any other suitable communications links, or any suitable combination of such links.

User devices 306 can include any one or more user devices suitable for initializing a simulation or initializing generation of a map, transmitting instructions to server 302 to generate one or more maps, generating a map using an N-dimensional array based on an underlying fractal, and/or performing any other suitable functions. In some embodiments, user devices 306 can include any suitable type(s) of user devices. For example, in some embodiments, user devices 306 can include a mobile phone, a tablet computer, a laptop computer, a desktop computer, and/or any other suitable type of user device.

Although server 302 is illustrated as one device, the functions performed by server 302 can be performed using any suitable number of devices in some embodiments. For example, in some embodiments, multiple devices can be used to implement the functions performed by server 302.

Although two user devices 308 and 310 are shown in FIG. 3 to avoid over-complicating the figure, any suitable number of user devices, and/or any suitable types of user devices, can be used in some embodiments.

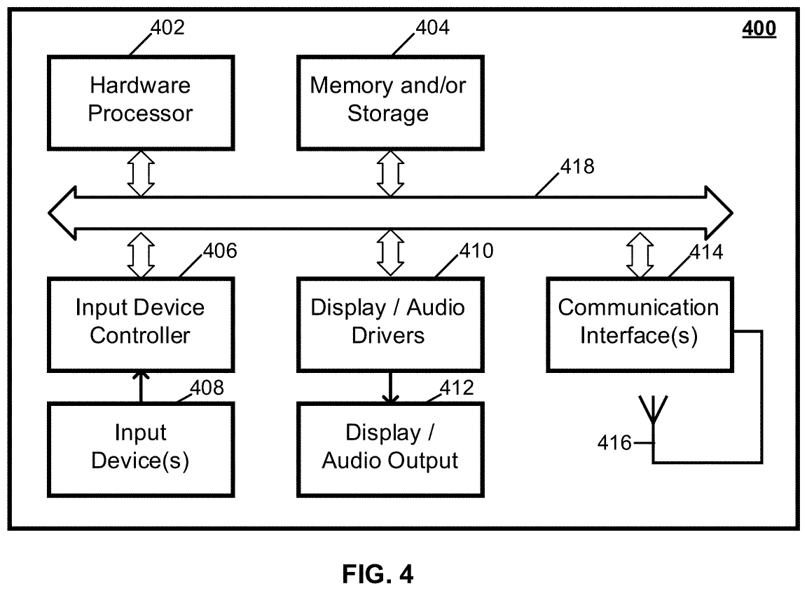

Server 302 and user devices 306 can be implemented using any suitable hardware in some embodiments. For example, in some embodiments, devices 302 and 306 can be implemented using any suitable general-purpose computer or special-purpose computer. For example, a mobile phone may be implemented using a special-purpose computer. Any such general-purpose computer or special-purpose computer can include any suitable hardware. For example, as illustrated in example hardware 400 of FIG. 4, such hardware can include hardware processor 402, memory and/or storage 404, an input device controller 406, an input device 408, display/audio drivers 410, display and audio output circuitry 412, communication interface(s) 414, an antenna 416, and a bus 418.

Hardware processor 402 can include any suitable hardware processor, such as a microprocessor, a micro-controller, digital signal processor(s), dedicated logic, and/or any other suitable circuitry for controlling the functioning of a general-purpose computer or a special-purpose computer in some embodiments. In some embodiments, hardware processor 402 can be controlled by a server program stored in memory and/or storage of a server, such as server 302. In some embodiments, hardware processor 402 can be controlled by a computer program stored in memory and/or storage of a user device, such as user device 306.

Memory and/or storage 404 can be any suitable memory and/or storage for storing programs, data, and/or any other suitable information in some embodiments. For example, memory and/or storage 404 can include random access memory, read-only memory, flash memory, hard disk storage, optical media, and/or any other suitable memory.

Input device controller 406 can be any suitable circuitry for controlling and receiving input from one or more input devices 408 in some embodiments. For example, input device controller 406 can be circuitry for receiving input from a touchscreen, from a keyboard, from one or more buttons, from a voice recognition circuit, from a microphone, from a camera, from an optical sensor, from an accelerometer, from a temperature sensor, from a near field sensor, from a pressure sensor, from an encoder, and/or any other type of input device.

Display/audio drivers 410 can be any suitable circuitry for controlling and driving output to one or more display/audio output devices 412 in some embodiments. For example, display/audio drivers 410 can be circuitry for driving a touchscreen, a flat-panel display, a cathode ray tube display, a projector, a speaker or speakers, and/or any other suitable display and/or presentation devices.

Communication interface(s) 414 can be any suitable circuitry for interfacing with one or more communication networks (e.g., computer network 304). For example, interface(s) 414 can include network interface card circuitry, wireless communication circuitry, and/or any other suitable type of communication network circuitry.

Antenna 416 can be any suitable one or more antennas for wirelessly communicating with a communication network (e.g., communication network 304) in some embodiments. In some embodiments, antenna 316 can be omitted.

Bus 418 can be any suitable mechanism for communicating between two or more components 402, 404, 406, 410, and 414 in some embodiments.

Any other suitable components can be included in hardware 300 in accordance with some embodiments.

In some embodiments, at least some of the above described blocks of the process of FIG. 1 can be executed or performed in any order or sequence not limited to the order and sequence shown in and described in connection with the figures. Also, some of the above blocks of FIG. 1 can be executed or performed substantially simultaneously where appropriate or in parallel to reduce latency and processing times. Additionally or alternatively, some of the above described blocks of the process of FIG. 1 can be omitted.

In some embodiments, any suitable computer readable media can be used for storing instructions for performing the functions and/or processes herein. For example, in some embodiments, computer readable media can be transitory or non-transitory. For example, non-transitory computer readable media can include media such as non-transitory forms of magnetic media (such as hard disks, floppy disks, and/or any other suitable magnetic media), non-transitory forms of optical media (such as compact discs, digital video discs, Blu-ray discs, and/or any other suitable optical media), non-transitory forms of semiconductor media (such as flash memory, electrically programmable read-only memory (EPROM), electrically erasable programmable read-only memory (EEPROM), and/or any other suitable semiconductor media), any suitable media that is not fleeting or devoid of any semblance of permanence during transmission, and/or any suitable tangible media. As another example, transitory computer readable media can include signals on networks, in wires, conductors, optical fibers, circuits, any suitable media that is fleeting and devoid of any semblance of permanence during transmission, and/or any suitable intangible media.

Accordingly, methods, systems, and media for generative urban design where maps are generated using fractals are provided.

Although the invention has been described and illustrated in the foregoing illustrative embodiments, it is understood that the present disclosure has been made only by way of example, and that numerous changes in the details of implementation of the invention can be made without departing from the spirit and scope of the invention. Features of the disclosed embodiments can be combined and rearranged in various ways.

What is claimed is:

1. A method for generative design, the method comprising:
identifying, using a hardware processor, area information for a particular geographic location;
identifying, using the hardware processor, fractal generation parameters;
generating, using the hardware processor, a fractal using the fractal generation parameters;
generating, using the hardware processor, an array that represents the particular geographic location based on the fractal and the area information; and
generating, using the hardware processor, one or more maps of the particular geographic location using the array.

2. The method of claim 1, further comprising:
receiving a distribution of different land use types for the particular geographic location; and
assigning one or more regions of the particular geographic location to one of a plurality of areas based on the distribution of different land use types for the particular geographic location.

3. The method of claim 1, wherein the array that represents the particular geographic location divides the particular geographic location into a plurality of cells each having a cell value and wherein each cell of the plurality of cells is assigned to a land use type from a plurality of land use types based on the cell value.

4. The method of claim 3, wherein a first range of cell values is assigned to a residential area, a second range of cell values is assigned to a commercial area, and a third range of cell values is assigned to a green space area.

5. The method of claim 1, wherein the array is an N-dimensional array and wherein the fractal is generated using a fractal generation algorithm.

6. The method of claim 5, wherein a cell of the N-dimensional array is associated with a vector having elements that correspond to each of a plurality of land use types, and wherein the vector indicates that a portion of the particular geographic location is allocated to a first percentage of residential area, a second percentage of commercial area, and a third percentage of green space area.

7. The method of claim 1, wherein the fractal generation parameters include a roughness parameter that modifies a roughness of edges within the fractal, wherein the fractal is generated using the roughness parameter, wherein a high roughness parameter scatters a land use type across the array, and wherein a low roughness parameter generates clusters of the land use area in the array.

8. A system for generative design, the system comprising:
a memory; and
a hardware processor that, when configured to execute computer executable instructions stored in the memory, is configured to:
identify area information for a particular geographic location;
identify fractal generation parameters;
generate a fractal using the fractal generation parameters;
generate an array that represents the particular geographic location based on the fractal and the area information; and
generate one or more maps of the particular geographic location using the array.

9. The system of claim 8, wherein the hardware processor is further configured to:
receive a distribution of different land use types for the particular geographic location; and
assign one or more regions of the particular geographic location to one of a plurality of areas based on the distribution of different land use types for the particular geographic location.

10. The system of claim 8, wherein the array that represents the particular geographic location divides the particular geographic location into a plurality of cells each having a cell value and wherein each cell of the plurality of cells is assigned to a land use type from a plurality of land use types based on the cell value.

11. The system of claim 10, wherein a first range of cell values is assigned to a residential area, a second range of cell values is assigned to a commercial area, and a third range of cell values is assigned to a green space area.

12. The system of claim 8, wherein the array is an N-dimensional array and wherein the fractal is generated using a fractal generation algorithm.

13. The system of claim 12, wherein a cell of the N-dimensional array is associated with a vector having elements that correspond to each of a plurality of land use types, and wherein the vector indicates that a portion of the particular geographic location is allocated to a first percentage of residential area, a second percentage of commercial area, and a third percentage of green space area.

14. The system of claim 8, wherein the fractal generation parameters include a roughness parameter that modifies a roughness of edges within the fractal, wherein the fractal is generated using the roughness parameter, wherein a high roughness parameter scatters a land use type across the array, and wherein a low roughness parameter generates clusters of the land use area in the array.

15. A non-transitory computer-readable medium containing computer executable instructions that, when executed by a processor, cause the processor to perform a method for generative design, the method comprising:
identifying, using a hardware processor, area information for a particular geographic location;
identifying, using the hardware processor, fractal generation parameters;
generating, using the hardware processor, a fractal using the fractal generation parameters;
generating, using the hardware processor, an array that represents the particular geographic location based on the fractal and the area information; and
generating, using the hardware processor, one or more maps of the particular geographic location using the array.

16. The non-transitory computer-readable medium of claim 15, wherein the method further comprises:
receiving a distribution of different land use types for the particular geographic location; and
assigning one or more regions of the particular geographic location to one of a plurality of areas based on the distribution of different land use types for the particular geographic location.

17. The non-transitory computer-readable medium of claim 15, wherein the array that represents the particular geographic location divides the particular geographic location into a plurality of cells each having a cell value and wherein each cell of the plurality of cells is assigned to a land use type from a plurality of land use types based on the cell value.

18. The non-transitory computer-readable medium of claim 17, wherein a first range of cell values is assigned to a residential area, a second range of cell values is assigned to a commercial area, and a third range of cell values is assigned to a green space area.

19. The non-transitory computer-readable medium of claim 15, wherein the array is an N-dimensional array and wherein the fractal is generated using a fractal generation algorithm.

20. The non-transitory computer-readable medium of claim 19, wherein a cell of the N-dimensional array is associated with a vector having elements that correspond to each of a plurality of land use types, and wherein the vector indicates that a portion of the particular geographic location is allocated to a first percentage of residential area, a second percentage of commercial area, and a third percentage of green space area.

21. The non-transitory computer-readable medium of claim 15, wherein the fractal generation parameters include a roughness parameter that modifies a roughness of edges within the fractal, wherein the fractal is generated using the roughness parameter, wherein a high roughness parameter scatters a land use type across the array, and wherein a low roughness parameter generates clusters of the land use area in the array.
